(19) United States
(12) Patent Application Publication
(10) Pub. No.: US 2006/0110910 A1
(43) Pub. Date: May 25, 2006

(54) Method for forming landing plug poly of semiconductor device

(76) Inventors: Jung Seock Lee, Seoul (KR); Ki Won Nam, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/123,557

(22) Filed: May 6, 2005

(30) Foreign Application Priority Data
Nov. 19, 2004 (KR) 10-2004-0094952

(51) Int. Cl. H01L 21/4763; H01L 21/44; H01L 21/336

(52) U.S. Cl. 438/621; 438/618; 438/597; 438/279

(57) ABSTRACT

Disclosed is a method for forming a landing plug poly of a semiconductor device. In such a method, there is provided a substrate formed with gates, each of which has a nitride film as a gate hard mask and nitride film spacers. An insulating interlayer is formed over the entire surface of the substrate and then is subjected to CMP until the nitride film is exposed. A material film having etching selectivity to the nitride film is deposited on the resultant substrate structure. The material film is patterned and the exposed insulating interlayer portions are etched to form a landing plug contact which simultaneously exposes several gates and substrate regions between the gates. A polysilicon film is deposited to fill up the landing plug contact. Finally, the polysilicon film is subjected to CMP until the gates are exposed.

### BACKGROUND OF THE INVENTION

1. Field of the Invention

The present invention relates generally to a method for forming a landing plug poly of a semiconductor device, and more particularly to a method for forming a landing plug poly of a semiconductor device, which can prevent a nitride film as a gate hard mask from being attacked during etching of a hard mask for forming a landing plug contact, thereby increasing an insulation margin between a gate line and a bit line.

2. Description of the Prior Art

With the progress of high integration of semiconductor devices, a contact size becomes decreased together with substantial reduction in area of a unit cell in order to provide a confined space with more unit cells when a semiconductor device is manufactured. As a result of this, there is difficulty in forming a Landing Plug Contact (LPC) for electrically connecting a silicon substrate to a bit line and a capacitor. To solve this problem, one technology called a Self Aligned Contact (SAC) technology has been proposed.

In such an SAC technology, a Landing Plug Contact (LPC) for exposing cell regions to be formed with a bit line and a capacitor is formed and then is filled up with a Landing Plug Poly (LPP) for both the bit line and the capacitor, thereby facilitating to electrically connecting a silicon substrate to the bit line and the capacitor to be subsequently formed.

FIGS. 1A to 1H illustrate sectional views showing a process of forming a landing plug poly of a semiconductor device according to the prior art.

Referring to FIG. 1A, a gate oxide film (not shown), a polysilicon film 11 and a tungsten film 12 are successively formed on a silicon substrate 10 on which a device separating film has been formed, and a nitride film 13 as a gate hard mask is formed on the tungsten film 12. Thereafter, a mask is formed on the nitride film 13 according to any well-known process, the nitride film 13 is etched using the mask, and then the tungsten film 12 and the polysilicon film 11 are etched using the etched nitride film 13 as a hard mask to form gate electrodes 14.

Referring to FIG. 1B, gate spacers 15 made of a nitride film are formed on sidewalls of the gate electrodes 14.

Referring to FIG. 1C, an insulating interlayer 16 is formed over the entire surface of the substrate and then is subjected to Chemical Mechanical Polishing (CMP) until the nitride film 13 as a gate hard mask is exposed.

Referring to FIG. 1D, a nitride film 17 is deposited as a hard mask for forming a landing plug poly. Thereafter, a photosensitive film is deposited on the nitride film 17 and then is exposed to light and developed to form a photosensitive film pattern 18 which exposes the nitride film above regions to be formed with a landing plug contact.

Referring to FIG. 1E, the hard mask 17 for forming a landing plug contact is etched using the photosensitive film pattern 18.

Referring to FIG. 1F, the insulating interlayer portions having been exposed by the etching of the hard mask are etched to form a landing plug contact 19 which simultaneously exposes several gates and substrate regions between the gates.

Referring to FIG. 1G, in a state where the photosensitive film pattern is removed, a polysilicon film 20 is deposited on the resultant substrate structure such that the landing plug contact is filled up.

Referring to FIG. 1H, the polysilicon film and the residual nitride film as a gate hard mask are subjected to CMP until the gates 14 are exposed. In this way, a landing plug poly 20a of a semiconductor device is formed.

According to the conventional forming method of a landing plug poly as stated above, the etching process of the nitride film as a hard mask for forming a landing plug contact is performed in an etching equipment using a mixture gas of CF₄, O₂ and Ar. Here, since both the hard mask for forming a landing plug contact and the gate hard mask are formed of a nitride film, there is no etching selectivity between both the hard masks with the result that the nitride film as a gate hard mask suffers from an attack during the etching of the hard mask for forming a landing plug contact.

Consequently, the nitride film as a gate hard mask is simultaneously etched to produce a peak-shaped upper surface of the etched nitride film as designated by reference numeral ‘A’ in FIG. 1E. Thereafter, once the insulating film between the gates is removed by means of the SAC process, the peak-shaped portions are more and more inclined. When the polysilicon film is deposited and then a CMP process for separating a storage node contact and a bit line contact node is performed so as to form a landing plug poly, these peak-shaped portions comes to reduce a distance between the nodes.

Also, in order to remove the peak-shaped portions, CMP must be performed up to an increased depth, which incurs a problem in that the thickness of the nitride film as a gate hard mask is decreased and thus an insulation margin between a bit line and a gate line is reduced during subsequent etching of a bit line contact hole.

### SUMMARY OF THE INVENTION

Accordingly, the present invention has been made to solve the above-mentioned problem occurring in the prior art, and an object of the present invention is to provide a method for forming a landing plug poly of a semiconductor device, which can prevent a nitride film as a gate hard mask from being attacked during etching of a hard mask for forming a landing plug contact, thereby increasing an insulation margin between a gate line and a bit line.

In order to accomplish this object, there is provided a method for forming a landing plug poly of a semiconductor device in accordance with the present invention, the method comprising the steps of: providing a substrate being formed with gates, each of which has a nitride film as a gate hard mask on its top and also has nitride film spacers on its sidewalls; forming an insulating interlayer over the entire surface of the substrate; performing CMP of the insulating interlayer until the nitride film as a gate hard mask is exposed; depositing a material film having etching selectivity to the nitride film as a gate hard mask on the resultant substrate structure; patterning the material film and etching insulating interlayer portions exposed by the patterning of the material film to form a landing plug contact which simultaneously exposes several gates and substrate regions between the gates; depositing a polysilicon film to fill up the landing plug contact; and performing CMP of the polysilicon film until the gates are exposed.

The material film is preferably an Organic Bottom Anti-Reflective Coating (OBARC) film.

It is preferred that an etching selectivity ratio between the material film and the nitride film as a gate hard mask is about 2:1.

Preferably, the material film is etched using a mixture gas of CO, O₂ and Ar, and a flow rate of CO is about 50 to 150 sccm, a flow rate of O₂ is about 5 to 30 sccm and a flow rate of Ar is about 200 to 800 sccm.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1H are process-by-process sectional views for explaining a method for forming a landing plug poly of a semiconductor device according to the prior art; and

FIGS. 2A to 2H are process-by-process sectional view for explaining a method for forming a landing plug poly of a semiconductor device in accordance with a preferred embodiment of the present invention.

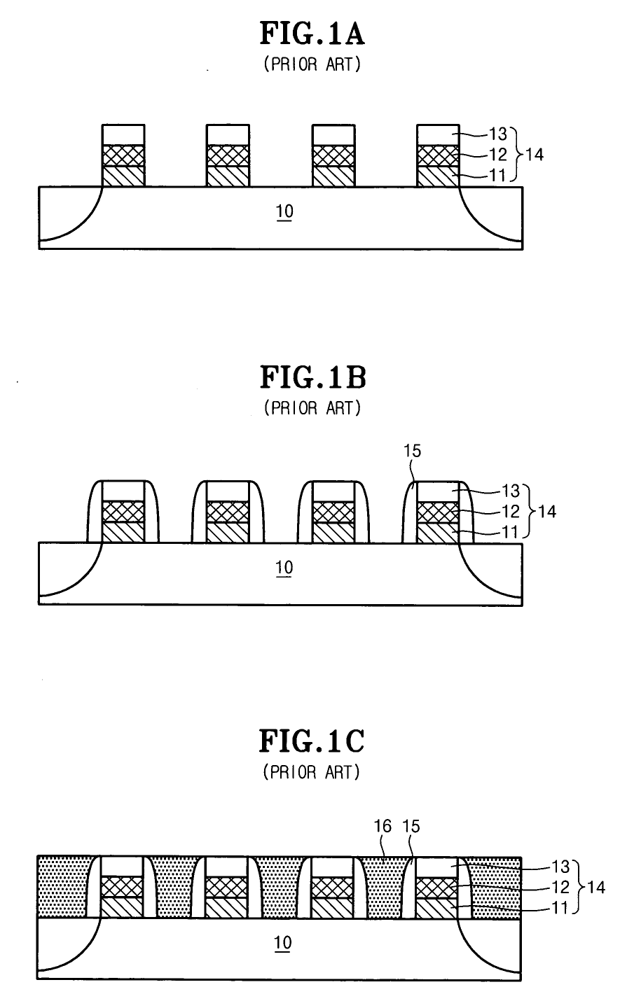

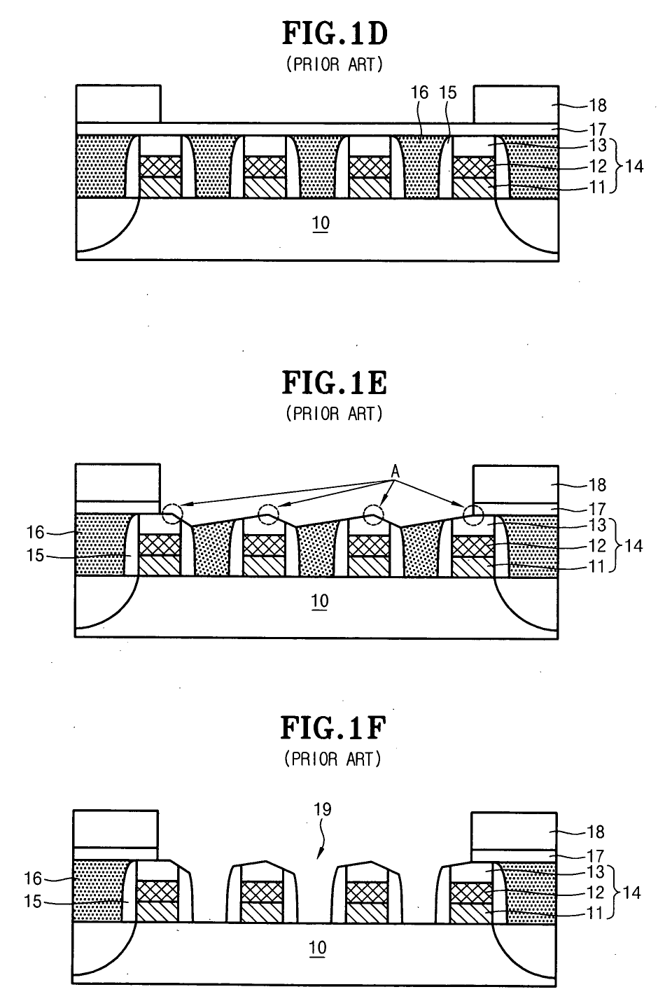

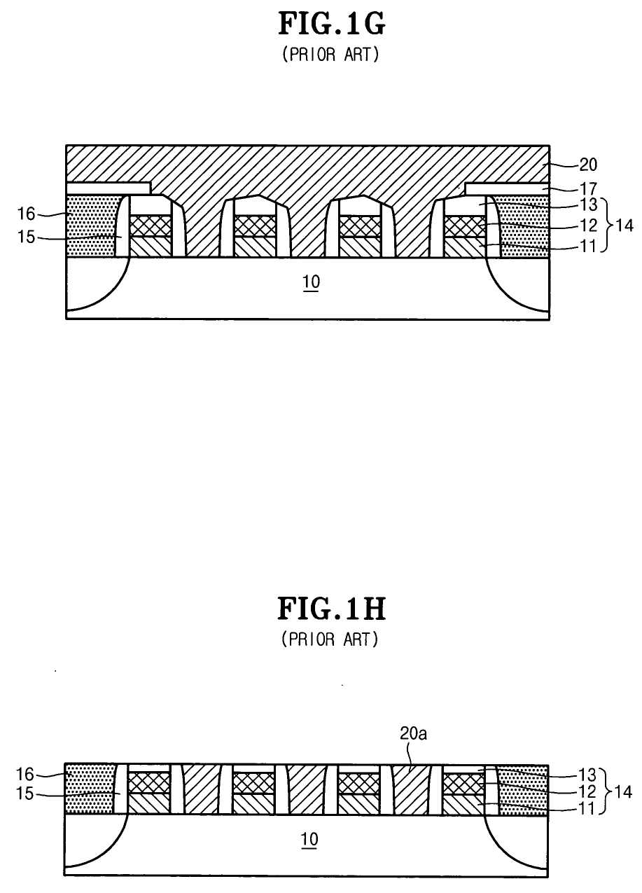

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

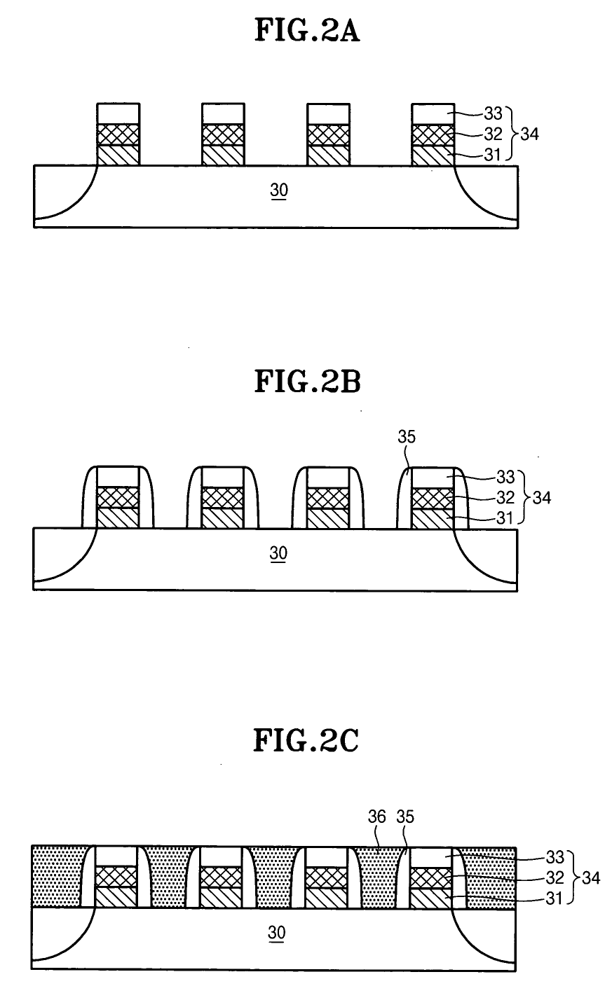

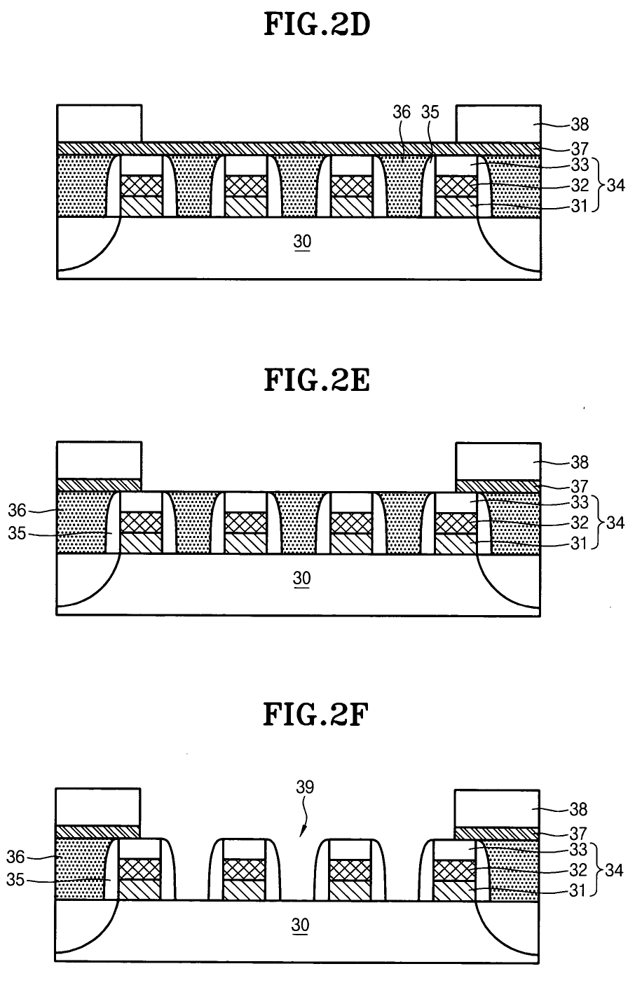

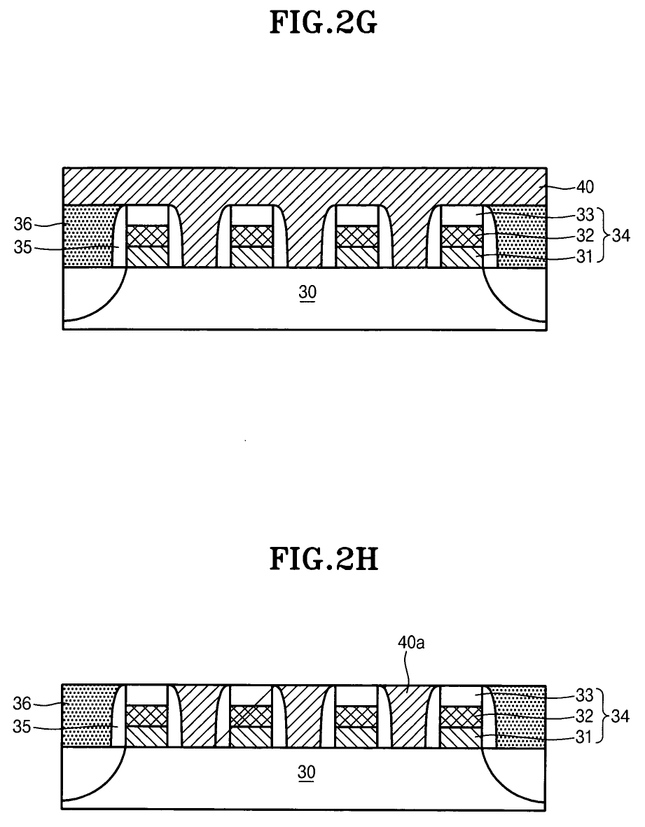

FIGS. 2A to 2H illustrate process-by-process sectional view for explaining a method for forming a landing plug poly of a semiconductor device in accordance with a preferred embodiment of the present invention, based upon which the following description will be given.

Referring to FIG. 2A, a gate oxide film (not shown), a polysilicon film 31 and a tungsten film 32 are successively formed on a silicon substrate 30 on which a device separating film has been formed, and a nitride film 33 as a gate hard mask is formed on the tungsten film 32. Thereafter, a mask is formed on the nitride film 33 according to any well-known process, the nitride film 33 is etched using the mask, and then the tungsten film 32 and the polysilicon film 31 are etched using the etched nitride film 33 as a hard mask to form gate electrodes 34.

Referring to FIG. 2B, gate spacers 35 made of a nitride film are formed on sidewalls of the gate electrodes 34 according to any well-known process.

Referring to FIG. 2C, an insulating interlayer 36 is formed over the entire surface of the resultant substrate structure formed up to the above-mentioned process and then is subjected to CMP until the nitride film 33 as a hard mask of the gate electrodes 34 is exposed.

Referring to FIG. 2D, a material film 37 as a hard mask for forming a landing plug contact, for example, an OBARC film is deposited on the resultant substrate structure. At this time, an etching selectivity ratio between the material film 37 as a hard mask for forming a landing plug contact, that is, the OBARC film and the nitride film 33 as a hard mask of the gate electrodes 34 is preferably about 2:1.

Thereafter, a photosensitive film is coated on the material film 37 and then is exposed to light and developed to form a photosensitive film pattern 38 which exposes the nitride film above regions to be formed with a landing plug contact.

Referring to FIG. 2E, the material film 37 as a hard mask for forming a landing plug contact is etched using the photosensitive film pattern 38 as an etching barrier. At this time, the material film 37 is etched using a mixture gas of CO, O₂ and Ar. From among components of the mixture gas, CO has a flow rate of about 50 to 150 sccm. Also, a flow rate of O₂ is about 5 to 30 sccm in order to realize favorable etching and to lower etching rate for the insulating interlayer 36, and a flow rate of Ar used as a diluting gas is about 200 to 800 sccm.

Referring to FIG. 2F, the insulating interlayer portions having been exposed by the etching of the material film are etched according to an SAC process to thereby form a landing plug contact 39 which simultaneously exposes several gate electrodes 34 and substrate regions between the gate electrodes 34.

Referring to FIG. 2G, in a state where the photosensitive film pattern is removed, a polysilicon film 40 is deposited on the resultant substrate structure such that the landing plug contact is filled up.

Next, as shown in FIG. 2H, the polysilicon film is subjected to CMP until the gate electrodes 34 are exposed. In this way, a landing plug poly 40a is formed between the gate electrodes 34.

When the material film having etching selectivity to the nitride film as a gate hard mask is deposited as a hard mask for forming a landing plug contact, an attack against the nitride film as a gate hard mask of the prior art can be prevented. Therefore, the nitride film as a gate hard mask can possess a certain thickness because its upper portion is not damaged, so that a process margin can be ensured when CMP for the separation between nodes is performed.

Also, when the OBARC film is used as a hard mask for forming a landing plug contact, the residual OBARC film can be removed simultaneously with the photosensitive film used as a mask, which provides an advantage of simplifying process steps.

As described above, in the method for forming a landing plug poly of a semiconductor device according to the present invention, a nitride film as a hard mask for forming a landing plug contact can be etched without making an attack against a nitride film as a gate hard mask due to no etching selectivity between both the hard masks, so that a process margin between a gate line and a bit line can be increased. Also, when a material film used as a hard mask for forming a landing plug contact is an OBARC film, the residual OBARC film can be removed simultaneously with a photosensitive film used as a mask, which provides an advantage of simplifying process steps. Accordingly, the present invention not only can ensure reliability of a landing plug poly itself, but also can improve reliability of a semiconductor device and production yield.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for forming a landing plug poly of a semiconductor device, the method comprising the steps of:
providing a substrate being formed with gates, each of which has a nitride film as a gate hard mask on its top and also has nitride film spacers on its sidewalls;
forming an insulating interlayer over the entire surface of the substrate;
performing CMP of the insulating interlayer until the nitride film as a gate hard mask is exposed;
depositing a material film having etching selectivity to the nitride film as a gate hard mask on the resultant substrate structure;
patterning the material film and etching insulating interlayer portions exposed by the patterning of the material film to form a landing plug contact which simultaneously exposes several gates and substrate regions between the gates;
depositing a polysilicon film to fill up the landing plug contact; and
performing CMP of the polysilicon film until the gates are exposed.

2. The method as claimed in claim 1, wherein the material film is an Organic Bottom Anti-Reflective Coating (OBARC) film.

3. The method as claimed in claim 1, wherein an etching selectivity ratio between the material film and the nitride film as a gate hard mask is about 2:1.

4. The method as claimed in claim 1, wherein the material film is etched using a mixture gas of CO, 02 and Ar.

5. The method as claimed in claim 4, wherein a flow rate of CO is about 50 to 150 sccm, a flow rate of O₂ is about 5 to 30 sccm and a flow rate of Ar is about 200 to 800 sccm.
